(19) United States
(12) Patent Application Publication
(10) Pub. No.: US 2006/0024535 A1
(43) Pub. Date: Feb. 2, 2006

(54) CO tolerant catalyst

(76) Inventors: Juan C. Figueroa, Wilmington, DE (US); Cynthia Anne Lundgren, Rising Sun, MD (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/049,541

(22) Filed: Feb. 2, 2005

Related U.S. Application Data
(60) Provisional application No. 60/541,661, filed on Feb. 4, 2004.

(51) Int. Cl. H01M 8/00; C23C 14/32

(52) U.S. Cl. 429/12; 204/192.15

(57) ABSTRACT

A catalyst comprises vapor-deposited, at least partially de-alloyed PtXₐAl_{b}, wherein X is Mo or W, a is at least 0.001 and b is at least 2.4(1+a). The catalyst is particularly useful as an electro-oxidation catalyst in a fuel cell and is preferred for use in a reformate fuel cell.

### FIELD OF THE INVENTION

The present invention relates to a catalyst composition. More specifically, it relates to a catalyst composition which is suitable for use in a fuel cell and which has carbon monoxide (CO) tolerance in operation.

### BACKGROUND OF THE INVENTION

Fuel cells are electrochemical cells in which a free energy change resulting from a fuel oxidation reaction is converted into electrical energy.

Two types of organic/air fuel cells are generally known:
1. An “indirect” or “reformer” fuel cell in which an organic fuel is catalytically reformed and processed into carbon monoxide-free hydrogen, with the hydrogen so obtained oxidized at the anode of the fuel cell.
2. A “direct oxidation” fuel cell in which the organic fuel is directly fed into the fuel cell without any previous chemical modification where the fuel is oxidized at the anode.

In reformer fuel cells, a hydrocarbon fuel source, such as, for example, gasoline, diesel, natural gas, ethane, butane, light distillates, dimethyl ether, methanol, ethanol, propane, naphtha, kerosene, and combinations thereof, is converted to a hydrogen-rich gas stream. In such a cell, a reactant or reducing fluid such as hydrogen is supplied to the anode electrode, and an oxidant such as oxygen or air is supplied to the cathode electrode. The hydrogen electrochemically reacts at a surface of the anode electrode to produce hydrogen ions and electrons. The electrons are conducted to an external load circuit and then returned to the cathode electrode, while hydrogen ions transfer through the electrolyte to the cathode electrode, where they react with the oxidant and electrons to produce water and release thermal energy.

Electrochemical fuel cells employ an electrolyte disposed between two electrodes, namely a cathode and an anode. Solid polymer fuel cells generally employ a membrane electrode assembly (“MEA”) consisting of a solid polymer electrolyte (SPE) or ion exchange membrane disposed between two electrode layers comprising porous, electrically conductive sheet material. The membrane is ion conductive (typically proton conductive), and also acts as a barrier for isolating the reactant streams from each other. Another function of the membrane is to act as an electrical insulator between the two electrode layers. An electrocatalyst is disposed at the interface between the electrolyte and the electrodes to induce the desired electrochemical reactions. The location of the electrocatalyst generally defines the electrochemically active area.

Both electrochemical reactions taking place in a fuel cell require Platinum (Pt) to operate at a feasible rate. However, Pt is easily poisoned by CO, and significant power losses may be experienced when hydrogen is obtained from reformation of alcohols or hydrocarbons. It has been reported that even as little as 10 parts per million (ppm) CO in the hydrogen can have a detrimental effect.

### SUMMARY OF THE INVENTION

In accordance with a first aspect, the present invention relates to a method comprising: (a) vapor depositing elemental Pt, X and Al on a substrate, wherein X is Mo or W, to yield a catalyst precursor having the formula PtXₐAl_{b}, wherein X is Mo or W, a is at least 0.001 and b is at least 2.4(1+a); and (b) activating the catalyst precursor to form a catalyst. The present invention also relates to a catalyst made by the above method.

According to another aspect, the present invention further relates to a composition of the formula PtXₐAl_{b}, wherein X is Mo or W, a is between 0.001 and 2.2, and b is less than 9.5, which, when coated on a substrate, has a CO stripping potential of less than 170 mV versus a saturated calomel electrode.

According to another aspect, the present invention further relates to a composition having a CO stripping potential of less than 170 mV versus a saturated calomel electrode.

According to another aspect, the present invention further relates to a fuel cell comprising a chamber, a membrane separating the chamber into an anode compartment and a cathode compartment, wherein the membrane is at least partially coated with the compositions described above.

According to a further aspect, the present invention relates to a membrane electrode assembly comprising anode and cathode layers of porous electrically conductive sheet material, a membrane interposed therebetween and the compositions described above interposed between the anode layer and the membrane.

According to another aspect, the present invention further relates to a method of increasing the CO tolerance of a membrane electrode assembly, comprising anode and cathode layers of porous electrically conductive sheet material, a membrane interposed therebetween, by vapor depositing elemental Pt, X and Al on a membrane, wherein X is Mo or W, to yield a catalyst precursor having the formula PtXₐAl_{b}, wherein X is Mo or W, a is at least 0.001 and b is at least 2.4(1+a); and activating the catalyst precursor to form a catalyst.

### DETAILED DESCRIPTION

Unless stated otherwise, all percentages, parts, ratios, etc., are by weight.

All patents, patent applications, and publications referred to herein are incorporated by reference in their entirety.

Further, when an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

As used herein, “fluid” shall include any material in the liquid or gaseous state.

As used herein, “activated” or variations thereof shall mean the attainment of practical catalytic activity for a given precursor formulation upon its exposure to a chemical treatment, wherein it is in a material state simultaneously displaying catalytic properties, electron-conductive properties, proton-conductive properties and fluid transport properties.

As used herein, “precursor” means a material that does not have useful electrocatalytic activity, wherein upon activation, attains a useful electrocatalystic activity.

As used herein, “vapor depositing” or variations thereof, shall mean a physical phase transformation process by which a gas transforms into a solid layer deposited on the surface of a solid substrate.

According to a first aspect, the present invention relates to a catalyst comprising vapor-deposited, at least partially de-alloyed PtXₐAl_{b}, wherein X is Mo or W, is at least 0.001 and b is at least 2.4(1+a).

Any known vapor-deposition technique is considered suitable. By way of illustrative example, vapor-deposition techniques can be generally categorized as chemical vapor-deposition techniques and physical deposition techniques.

The fundamental chemical vapor deposition process typically comprises:
(a) vaporization and transport of precursor molecules into a reactor,
(b) diffusion of the precursor molecules to a surface,
(c) adsorption of the precursor molecules to the surface,
(d) decomposition of the precursor molecules on the surface and incorporation into solid films, and
(e) recombination of molecular byproducts and desorption into the gas phase.

Illustrative chemical vapor deposition techniques include atmospheric pressure chemical vapor deposition, low-pressure chemical vapor deposition, plasm assisted (enhanced) chemical vapor deposition, photochemical vapor deposition, laser chemical vapor deposition, metal-organic chemical vapor deposition, chemical beam epitaxy and chemical vapor infiltration.

Physical vapor deposition methods are generally clean, dry vacuum deposition methods in which a coating is deposited over an entire object simultaneously, rather than in localized areas. Physical vapor-deposition methods generally combine:
(a) a method for depositing a metal
(b) combination with an active gas, such as nitrogen, oxygen or methane, and
(c) plasma bombardment of the substrate.
   Physical vapor-deposition methods differ in the means for producing the metal vapor and the details of the plasma creation. Illustrative physical vapor-deposition methods include ion plating, ion implantation, sputtering and laser surface alloying.

Sputtering is the preferred method for vapor-depositing the catalyst precursor. Magnetron sputtering is most preferred.

The catalyst is at least partially dealloyed, that is, chemically treated so as to remove at least some of the aluminum therefrom. The preferred dealloying comprises treating the catalyst precursor with caustic, preferably a caustic solution. The preferred treatment is immersion of the precursor in a solution of NaOH.

Preferably, the catalyst precursor is coated on a substrate. As noted above, electrochemical fuel cells employ an electrolyte disposed between two electrodes, namely a cathode and an anode. Solid polymer fuel cells generally employ a membrane electrode assembly (“MEA”) in which the electrolyte comprises a solid polymer electrolyte (SPE), which is an ion exchange membrane, disposed between the two electrode layers comprising porous, electrically conductive sheet material. The SPE is ion conductive (typically proton conductive), and also acts as a barrier for isolating the reactant streams from each other. Another function of the membrane is to act as an electrical insulator between the two electrode layers. An electrocatalyst is disposed at the interface between the SPE and the electrodes to induce the desired electrochemical reactions. Thus, an electro-oxidation catalyst is used at the interface between the SPE and the anode, and an electro-reduction catalyst is used at the interface between the SPE and the cathode.

Catalyst in accordance with the present invention is particularly well suited as an electro-oxidation catalyst in a fuel cell. Accordingly, in accordance with one aspect of the present invention, the electrocatalyst can be applied to the surface of the SPE, which faces the anode, to the surface of the anode facing the SPE, or to both surfaces. In accordance with another aspect, the substrate comprises a SPE. In accordance with a further aspect, the substrate comprises an electrode, preferably an anode.

In accordance with another aspect of the invention, the catalyst can be applied to the surface or interpenetrated within the porous, electrically conductive sheet material. This porous conductive sheet material can comprise paper or cloth made from woven or non-woven carbon fiber. Some useful porous conductive sheet materials include, but are not limited to, graphite papers obtainable from Toray (Tokyo, Japan), Spectracorp (Lawrence, Mass.), Lydall Inc. (Manchester, Conn.) or SGL Carbon (Wiesbaden, Germany) and Zoltek® carbon cloth obtainable from Zoltek Companies; Inc (St. Louis, Mo.). A microporous layer that may be applied to the porous conductive sheet materials may comprise a coating of carbon particles and a hydrophobic binder. For example, carbon particles such as Vulcan XC-72 may be mixed with a hydrophobic binder such as polyvinylidene difluoride (PVDF), e.g. Kynar®, or a sulfonyl fluoride copolymer, e.g. Nafion®.

In accordance with another aspect of the present invention, a fuel cell comprises a chamber and a membrane separating the chamber into an anode compartment and a cathode compartment, wherein the membrane is at least partially coated with a catalyst comprising vapor-deposited, at least partially de-alloyed PtXₐAl_{b}, wherein X is Mo or W, a is at least 0.001 and b is at least 2.4(1+a). Preferably, the membrane comprises a first surface facing the anode chamber and a second surface facing the cathode chamber and the catalyst is at least partially coated on the first surface. Also preferably, the anode chamber contains reformate fuel.

In accordance with another aspect of the present invention, a fuel cell comprises a chamber and a membrane separating the chamber into an anode compartment and a cathode compartment, wherein the membrane is at least partially coated with a catalyst comprising vapor-deposited, at least partially de-alloyed PtXₐAl_{b}, wherein X is Mo or W, a is at least 0.001 and b is at least 2.4(1+a). Preferably, the membrane comprises a first surface facing the anode chamber and a second surface facing the cathode chamber and the catalyst is at least partially coated on the first surface. Also preferably, the anode chamber contains reformate fuel.

In accordance with a further aspect of the present invention, a catalyst is provided having a CO stripping potential of less than 170 mV versus a saturated calomel electrode. Preferably, the CO stripping potential of the catalyst is less than 100 mV versus a saturated calomel electrode.

Preferably, catalyst in accordance with the present invention is made by:
(a) vapor depositing elemental Pt, X and Al on a substrate, wherein X is Mo or W to yield a catalyst precursor having the formula PtXₐAl_{b}, wherein X is Mo or W, a is at least 0.001 and b is at least 2.4(1+a); and
(b) activating the catalyst precursor.

Preferably, activating the catalyst precursor comprises immersion thereof in a caustic solution. Preferably, the vapor depositing comprises sputter depositing and is, preferably, conducted in an inert gas. Preferably, the inert gas is Argon. Also preferably, the vapor deposition is conducted at a pressure of 10⁻⁷ to 10⁻² Torr.

The ion exchange membrane (SPE) can be made by known extrusion or casting techniques and have thicknesses that can vary depending upon the intended application. The membranes typically have a thickness of 350 μm or less, although recently membranes that are quite thin, i.e., 50 μm or less, are being employed. While the polymer can be in alkali metal or ammonium salt form, it is typical for the polymer in the membrane to be in acid form to avoid post treatment acid exchange steps. Suitable perfluorinated sulfonic acid polymer membranes in acid form are available under the trademark Nafion® by E.I. du Pont de Nemours and Company.

Reinforced perfluorinated ion exchange polymer membranes can also be utilized. Reinforced membranes can be made by impregnating porous, expanded PTFE (ePTFE) with ion exchange polymer. ePTFE is available under the tradename “Goretex” from W. L. Gore and Associates, Inc., Elkton, Md., and under the tradename “Tetratex” from Tetratec, Feasterville, Pa. Impregnation of ePTFE with perfluorinated sulfonic acid polymer is disclosed in U.S. Pat. Nos. 5,547,551 and 6,110,333.

Alternately, the ion exchange membrane can be a porous support. A porous support may improve mechanical properties for some applications and/or decrease costs. The porous support can be made from a wide range of components, including hydrocarbons and polyolefins, e.g., polyethylene, polypropylene, polybutylene, copolymers of these matrials including polyolefins, and the like. Perhalogenated polymers such as polychlorotrifluoroethylene can also be used. The membrane can also be made from a polybenzimadazole polymer, for example, by casting a solution of polybenzimadazole in phosphoric acid (H₃PO₄) doped with trifluoroacetic acid (TFA) as described in U.S. Pat. Nos. 5,525,436, 5,716,727, 6,025,085 and 6,099,988.

The anode can be formed, by way of illustrative example, from the catalyst according to the present invention applied on a carbon fiber sheet backing used to make electrical contact with the particles of the electrocatalyst. Commercially available Toray™ paper can be used as the electrode backing sheet.

Also by way of illustrative example, the cathode is a gas diffusion electrode preferably formed from unsupported or supported platinum bonded to a side of the SPE opposite to the anode. Unsupported platinum black (fuel cell grade) available from Johnson Matthey Inc., USA or supported platinum materials available from E-Tek Inc., USA is suitable for the cathode. As with the anode, the cathode catalyst is preferably mounted on a carbon backing material. The electrocatalyst alloy and the carbon fiber backing can contain 10-50 weight percent Teflon™ to provide hydrophobicity needed to create a three-phase boundary and to achieve efficient removal of water produced by electro-reduction of oxygen.

In a fuel cell stack, the MEA is typically interposed between two separator plates that are substantially impermeable to the reactant fluid streams. The plates act as current collectors and provide support for the electrodes. To control the distribution of the reactant fluid streams to the electrochemically active area, the surfaces of the plates that face the MEA may have open-faced channels or grooves formed therein. Such channels or grooves define a flow field area that generally corresponds to the adjacent electrochemically active area. Such separator plates, which have reactant channels formed therein are commonly known as flow field plates. In a fuel cell stack a plurality of fuel cells is connected together, typically in series, to increase the overall output power of the assembly. In such an arrangement, one side of a given plate may serve as an anode plate for one cell and the other side of the plate may serve as the cathode plate for the adjacent cell. In this arrangement the plates may be referred to as bipolar plates.

It is desirable to seal reactant fluid stream passages in a fuel cell stack to prevent leaks or inter-mixing of the fuel and oxidant fluid streams. Fuel cell stacks typically employ fluid tight resilient seals, such as elastomeric gaskets between the separator plates and membranes. Such seals typically circumscribe the manifolds and the electrochemically active area. Sealing can be achieved by applying a compressive force to the resilient gasket seals. Compression enhances both sealing and electrical contact between the surfaces of the separator plates and the MEAs, and sealing between adjacent fuel cell stack components. In conventional fuel cell stacks, the fuel cell stacks are typically compressed and maintained in their assembled state between a pair of end plates by one or more metal tie rods or tension members. The tie rods typically extend through holes formed in the stack end plates, and have associated nuts or other fastening means to secure them in the stack assembly. The tie rods may be external, that is, not extending through the fuel cell plates and MEAs, however, external tie rods can add significantly to the stack weight and volume. It is generally preferable to use one or more internal tie rods that extend between the stack end plates through openings in the fuel cell plates and MEAs as described in U.S. Pat. No. 5,484,666. Typically resilient members are utilized to cooperate with the tie rods and end plates to urge the two end plates towards each other to compress the fuel cell stack.

The resilient members accommodate changes in stack length caused by, for example, thermal or pressure induced expansion and contraction, and/or deformation. That is, the resilient member expands to maintain a compressive load on the fuel cell assemblies if the thickness of the fuel cell assemblies shrinks. The resilient member may also compress to accommodate increases in the thickness of the fuel cell assemblies. Preferably, the resilient member is selected to provide a substantially uniform compressive force to the fuel cell assemblies, within anticipated expansion and contraction limits for an operating fuel cell. The resilient member can comprise mechanical springs, or a hydraulic or pneumatic piston, or spring plates, or pressure pads, or other resilient compressive devices or mechanisms. For example, one or more spring plates can be layered in the stack. The resilient member cooperates with the tension member to urge the end plates toward each other, thereby applying a compressive load to the fuel cell assemblies and a tensile load to the tension member.

### EXAMPLES

Procedures:

Carbon Monoxide Stripping Potential Using Cyclic Voltammetry (CV):

CVs are performed on coated carbon electrode strips in a solution of 0.5M H₂SO₄. A Pt counter-electrode and a saturated calomel electrode (SCE) as a reference are used. 100% CO is bubbled into the solution with the electrode at open circuit for 2 minutes. The potential of the electrode is set to −0.09V for 10 minutes. The gas is switched to N₂ and the solution is purged of CO for 10 minutes with the electrode still at −0.09V. The potential is then scanned to 0.55V and the CO stripping current is recorded. CVs are then performed from 0.55V to −0.25V, twice to get the base line current. The CO peak potential is a measure of the facility of the CO oxidation reaction. The more negative the voltage, the better the material is at facilitating CO oxidation.

### Electrode Fabrication

Electrodes containing ink-based catalysts were fabricated by depositing Nafion®/catalyst inks on Spectracarb® 2050A carbon paper covering 1.5 cm². Nafion® is available from E.I. DuPont de Nemours and Company of Wilmington, Del., and Spectracarb is available from SPECTRACORP of Lawrence, Mass.

Electrodes containing experimental catalysts were fabricated by vapor depositing the experimental ternary Pt precursor alloy onto a 1.5 cm² region of the Spectracarb® 2050A carbon papers using the following procedure:

### Experimental Catalyst Synthesis

The PtXₐAl_{b} (a>0, b>0) precursor was synthesized in a vapor deposition reactor that consisted of a water-cooled cylindrical stainless steel holder that rotated around its vertical axis. The Spectracarb® 2050A carbon paper substrate was fastened onto the holder at a given elevation. Four magnetron sputter vaporization sources, each using a 5 cm diameter target, were located around the holder at 90° from each other and radially faced the cylindrical holder. The elevation “z” of the substrate was defined as z=0. The elevation “z” of the center line of each magnetron sputter vaporization source was independently controlled and referred to that of the substrate. The position of a magnetron sputter vaporization source located above the substrate was defined by an elevation z>0; the position of a magnetron sputter vaporization source located below the substrate was defined by an elevation z<0.

A PtXₐAl_{b} (a>0, b>0) precursor was vapor deposited onto a moving 1 cm wide Spectracarb 2050A carbon paper substrate, properly masked to yield a 1.5 cm² coated surface region, by means of the sequential deposition of elemental Pt, X and Al vapors, each emitted from a separate magnetron sputter vaporization source. The rotating substrate was repeatedly exposed to the sequence of the different vapors. Control of the PtXₐAl_{b} stoichiometry was achieved via independent control of the ignition power fed to each magnetron sputter vaporization source and its elevation relative to that of the substrate. No external substrate heating was exercised during the vapor deposition step. For each synthesis, the vapor deposition system was pumped down to a pre-synthesis base pressure below 5·10⁻⁶ Torr, and it was subsequently back filled with flowing O₂ to a pressure of 50 mTorr to treat the substrate prior to vapor deposition of the precursor. To execute such substrate treatment, the cylindrical holder was RF ignited at 80 watts for 10 minutes to generate a glow discharge around the substrate. The gas flow was then switched from flowing O₂ to flowing Ar and the pressure was adjusted at 10 mTorr to conduct the vapor deposition of the precursor. Such synthesis took place on an electrically grounded substrate rotated at 5 RPM and total co-ignition time for vapor deposition was 10 minutes.

X-ray diffraction analysis of some precursor formulations indicated the existence of amorphous regions within these material as evidenced by the presence of a broad envelope in the 20°-30° scattering direction of the diffractogram. Such evidence is consistent with the expected quenching effect exerted by the water-cooled holder that facilitates amorphization during the synthesis of these aluminide materials.

Stoichiometric formulas were determined by inductively coupled spectroscopic analysis.

Subsequently, the Spectracarb 2050A carbon paper, having a 1.5 cm² region coated with the PtXₐAl_{b} precursor, was immersed for a minimum of 5 minutes and up to 120 minutes in a 20 wt % NaOH solution held at room temperature, followed by immersion for a minimum of 5 minutes and up to 120 minutes in a 20 wt % NaOH solution held at 80° C. Volume of the caustic solution was orders of magnitude larger than that at which caustic would be depleted.

Control 1:

Example 4 of U.S. Pat. No. 5,872,074 was repeated to prepare mechanically alloyed powders having the stoichiometric formula PtRuAl₈ from a mixture of elemental powders of Pt, Ru and Al using a SPEX 8000® grinder (SPEX CertiPrep, Wayne, N.J.) consisting of a WC crucible with three WC balls. The weight ratio of the balls to the powders was 4:1. The high energy ball milling operation lasted 40 hours. Particle size distribution analysis, scanning electron microscopy analysis and ICP analysis confirmed the findings claimed in U.S. Pat. No. 5,872,074. The prepared PtRuAl₈ powder was sonically mixed into a Nafion® 990 EW solution to yield an ink having 8 wt % solids in 92 wt % amyl alcohol solvent, with a solid weight ratio of 80% PtRuAl₈ powder and 20 wt % Nafion® 990 EW.

A Spectracarb 2050A carbon paper was painted with such ink to achieve a nominal loading of 0.65 mgₚₜ/cm² (milligram platinum per square centimeter) distributed over a 1.5 cm² region. The electrode was then subjected to a caustic activation treatment by immersing it for 15 minutes in a 20 wt % NaOH solution held at room temperature (RT), followed by immersion in a 20 wt % NaOH solution held at 80° C. for 15 minutes. Upon CO stripping testing such electrode showed a stripping potential of 238 mV versus SCE.

Control 2:

A water-based ink was prepared by mixing at room temperature for 15 min @ 15,000 RPM the following ingredients:

HISPEC 6000 powder (Johnson Matthey, Wayne, Pa.), Pt:Ru=1:1-0.08635 g
1 wt % Nafion®/water solution—1.25745 g
Water—4.64679 g

Such ink was deposited on a Toray carbon paper to an areal loading of 0.2 mgₚₜ/cm² to fabricate an electrode. Upon CO stripping testing, such electrode showed a stripping potential of 220 mV versus SCE.

### Example 1

Following the RF oxygen glow discharge treatment of the substrate as detailed in the experimental section above, the precursor was synthesized using the experimental catalyst synthesis procedure described above by coigniting a Pt magnetron sputter vaporization source, located at z=+2.0 cm, at 100 watts; a Mo magnetron sputter vaporization source, located at z=−5.5 cm, at 100 watts; an Al magnetron sputter vaporization source, located at z=−5.5 cm, at 400 watts; and an additional Al magnetron sputter vaporization source, located at z=+2.0 cm, at 400 watts. The so-formed semicrystalline precursor was subsequently activated by immersing it for 15 minutes in a 20 wt % NaOH solution held at RT, followed by immersion in a 20 wt % NaOH solution held at 80° C. for 15 minutes. The Spectracarb 2050A carbon paper having thereon a caustic-activated PtMo_{0.001}Al_{3.1} precursor showed a CO stripping potential of 105 mV versus SCE.

### Example 2

Following the RF oxygen glow discharge treatment of the substrate as detailed in the experimental section above, the precursor was synthesized using the experimental catalyst synthesis procedure described above by coigniting a Pt magnetron sputter vaporization source, located at z=+4.0 cm, at 100 wafts; a Mo magnetron sputter vaporization source, located at z=−3.5 cm, at 100 watts; an Al magnetron sputter vaporization source, located at z=−3.5 cm, at 400 watts; and an additional Al magnetron sputter vaporization source, located at z=+4.0 cm, at 400 watts. The so formed semicrystalline precursor was subsequently activated by immersing it for 15 minutes in a 20 wt % NaOH solution held at RT, followed by immersion in a 20 wt % NaOH solution held at 80° C. for 15 minutes. The Spectracarb 2050A carbon paper having thereon a caustic-activated PtMo_{2.1}Al_{9.4} precursor showed a CO stripping potential of 124 mV versus SCE.

### Example 3

Following the RF oxygen glow discharge treatment of the substrate as detailed in the experimental section above, the precursor was synthesized using the experimental catalyst synthesis procedure described above by coigniting a Pt magnetron sputter vaporization source, located at z=+3.0 cm, at 100 watts; a W magnetron sputter vaporization source, located at z=+1.0 cm, at 100 watts; an Al magnetron sputter vaporization source, located at z=−3.0 cm, at 400 watts; and an additional Al magnetron sputter vaporization source, located at z=+4.0 cm, at 400 watts. The so formed semicrystalline precursor was subsequently activated by immersing it for 15 minutes in a 20 wt % NaOH solution held at RT, followed by immersion in a 20 wt % NaOH solution held at 80° C. for 15 minutes. The Spectracarb 2050A carbon paper having thereon a caustic-activated PtW_{0.05}Al_{3.4} precursor showed a CO stripping potential of 68 mV versus SCE.

### Example 4

Following the RF oxygen glow discharge treatment of the substrate as detailed in the experimental section above, the precursor was synthesized using the experimental catalyst synthesis procedure described above by coigniting a Pt magnetron sputter vaporization source, located at z=+4.5 cm, at 100 watts; a W magnetron sputter vaporization source, located at z=+2.5 cm, at 100 watts; an Al magnetron sputter vaporization source, located at z=−1.5 cm, at 400 watts; and an additional Al magnetron sputter vaporization source, located at z=+5.5 cm, at 400 watts. The so formed semicrystalline precursor was subsequently activated by immersing it for 15 minutes in a 20 wt % NaOH solution held at RT, followed by immersion in a 20 wt % NaOH solution held at 80° C. for 15 minutes. The Spectracarb 2050A carbon paper having thereon a caustic-activated PtW_{1.2}Al_{9.5} precursor showed a CO stripping potential of 104 mV versus SCE.

What is claimed is:

1. A method comprising:
(a) vapor depositing elemental Pt, X and Al on a substrate, wherein X is Mo or W, to yield a catalyst precursor having the formula PtXₐAl_{b}, wherein X is Mo or W, a is at least 0.001 and b is at least 2.4(1+a); and
(b) activating the catalyst precursor to form a catalyst.

2. The method of claim 1, wherein activating the catalyst precursor comprises immersion thereof in caustic solution.

3. The method of claim 1, wherein the vapor depositing comprises sputter depositing.

4. The method of claim 1, wherein the vapor deposition is conducted in an inert gas.

5. The method of claim 4, wherein the inert gas comprises argon.

6. The method of claim 4, wherein the vapor deposition is conducted at a pressure of 10-7 to 10-2 Torr.

7. The method of claim 1 wherein the substrate comprises a solid polymer electrolyte or a porous, electrically conductive sheet material.

8. The method of claim 1, wherein the substrate comprises a fuel cell electrode.

9. The method of claim 1, wherein the catalyst precursor loading on the substrate is less than 4 mg/cm².

10. The method of claim 9, wherein the catalyst precursor loading on the substrate is less than 2 mg/cm².

11. The method of claim 10, wherein the catalyst precursor loading on the substrate is less than 1 mg/cm².

12. The method of claim 1 wherein the catalyst has a CO stripping potential of less than 170 mV versus a saturated calomel electrode.

13. The method of claim 12, wherein the CO stripping potential is less than 100 mV.

14. A catalyst made by the method of claim 1.

15. A fuel cell comprising a chamber, a membrane separating the chamber into an anode compartment and a cathode compartment, wherein the membrane is at least partially coated with the catalyst of claim 14.

16. The fuel cell of claim 15, wherein the membrane comprises a first surface facing the anode chamber and a second surface facing the cathode chamber and wherein the catalyst is at least partially coated on the first surface.

17. The fuel cell of claim 16, wherein the anode chamber contains reformate fuel.

18. A membrane electrode assembly comprising anode and cathode layers of porous electrically conductive sheet material, a membrane interposed therebetween and the catalyst of claim 14 interposed between the anode layer and the membrane.

19. A composition of the formula PtXₐAl_{b}, wherein X is Mo or W, a is between 0.001 and 2.2, and b is less than 9.5, which, when coated on a substrate, has a CO stripping potential of less than 170 mV versus a saturated calomel electrode.

20. The composition of claim 19, wherein the loading on the substrate is less than 4 mg/cm².

21. The composition of claim 20, wherein the loading on the substrate is less than 2 mg/cm².

22. The composition of claim 21, wherein the loading on the substrate is less than 1 mg/cm².

23. The composition of claim 19, wherein the substrate comprises a solid polymer electrolyte or a porous, electrically conductive sheet material.

24. The composition of claim 23, wherein the substrate comprises a fuel cell electrode.

25. A fuel cell comprising a chamber, a membrane separating the chamber into an anode compartment and a cathode compartment, wherein the membrane is at least partially coated with the composition of claim 19.

26. A composition having a CO stripping potential of less than 170 mV versus a saturated calomel electrode.

27. The composition of claim 26, wherein the CO stripping potential is less than 100 mV.

28. A membrane electrode assembly comprising anode and cathode layers of porous electrically conductive sheet material, a membrane interposed therebetween and catalyst interposed between the anode layer and the membrane, wherein the catalyst comprises the composition of claim 19.

29. A method of increasing the CO tolerance of a membrane electrode assembly, comprising anode and cathode layers of porous electrically conductive sheet material, a membrane interposed therebetween, by vapor depositing elemental Pt, X and Al on a membrane, wherein X is Mo or W, to yield a catalyst precursor having the formula PtXₐAl_{b}, wherein X is Mo or W, a is at least 0.001 and b is at least 2.4(1+a); and activating the catalyst precursor to form a catalyst.

30. The method of claim 29, wherein activating the catalyst precursor comprises immersion thereof in caustic solution.

31. The method of claim 29, wherein the vapor depositing comprises sputter depositing.

32. The method of claim 29, wherein the vapor deposition is conducted in an inert gas.

33. The method of claim 32, wherein the inert gas comprises argon.

34. The method of claim 29, wherein the vapor deposition is conducted at a pressure of 10⁻⁷ to 10⁻² Torr.

35. The method of claim 34 wherein the membrane comprises a solid polymer electrolyte.

36. The method of claim 29, wherein the catalyst precursor loading on the membrane is less than 4 mg/cm².

37. The method of claim 36, wherein the catalyst precursor loading on the membrane is less than 2 mg/cm².

38. The method of claim 37, wherein the catalyst precursor loading on the membrane is less than 1 mg/cm².

39. The method of claim 37 wherein the catalyst has a CO stripping potential of less than 170 mV versus a saturated calomel electrode.

40. The method of claim 39, wherein the CO stripping potential is less than 100 mV.
